(19) United States
(12) Patent Application Publication
(10) Pub. No.: US 2026/0362791 A1
(43) Pub. Date: Nov. 12, 2026

(54) PACKAGE OF BIDIRECTIONAL SWITCH WITH INSULATION LAYER FOR TOP SIDE COOLING

(71) Applicant: Monolithic Power Systems, Inc., Kirkland, WA (US)

(72) Inventors: Kwang-Soo Kim, Sunnyvale, CA (US); Di Han, San Jose, CA (US)

(21) Appl. No.: 19/201,623

(22) Filed: May 7, 2025

(51) Int. Cl. H10D 84/82; H10D 30/47; H10W 40/10; H10W 70/40

(52) U.S. Cl. CPC H10D 84/82; H10D 30/471; H10W 40/10; H10W 70/40

(57) ABSTRACT

The III-V semiconductor bidirectional switch bare die includes two III-V transistors that share part of the active device area and formed as a lateral device upon a single semiconductor body. A first gate electrode and a second gate electrode of the two III-V transistors are configured to receive two respective signals to control the III-V semiconductor bidirectional switch bare die to block and conduct currents from two directions. The III-V semiconductor bidirectional switch bare die is attached to an exposed pad of a lead frame. A heat sink is mounted to the exposed pad for achieving top side cooling. A layer of thermal interface material is inserted in between the heat sink and the exposed pad to ensure efficient heat transfer. One of a first source electrode and a second electrode of the two III-V transistors is electrically coupled to the exposed pad.

### TECHNICAL FIELD

Embodiments of the present invention relate to a package of bidirectional switch with insulation layer for top side cooling, and more particularly relate to a solution for elimination of noise emission of the package.

### BACKGROUND OF THE INVENTION

A bidirectional switch is a device capable of conducting and blocking current in both directions. By configuring two MOSFETs in either a common source arrangement or a common drain arrangement, the two MOSFETs together can perform as a bidirectional switch. However, this type of bidirectional switch doubles both the size and Rdson. A III-V semiconductor bidirectional switch bare die 10 shown in FIG. 1 includes two high-electron-mobility transistors (“HEMTs”) that share one same drift region can provide a Rdson approximately half of a bidirectional switch having two MOSFETs.

FIG. 1 schematically illustrates a cross-sectional side view of a package 100 of bidirectional switch for top side cooling. The package 100 includes a lead frame 20 that may further include an exposed pad 30 and a plurality of leads 301. A III-V semiconductor bidirectional switch bare die 10 where two III-V transistors share part of the active device area and formed as a lateral device upon a single semiconductor body may be arranged on the exposed pad 30 in such a manner that a substrate region 102 of the III-V semiconductor bidirectional switch bare die 10 directly attached to the exposed pad 30. To enhance the heat dissipation capability of the package 100, a heat sink 40, typically made of materials with high thermal conductivity such as copper or aluminum, is often attached to the exposed pad 30 with the help of a layer of thermal interface material (“TIM”) 60. The layer of TIM 60 ensures efficient heat transfer, provides mechanical stability and electrical insulation between the exposed pad 30 and the heat sink 40.

### SUMMARY OF THE INVENTION

Embodiments of the present invention are directed to a package of bidirectional switch. The package includes a heat sink, a lead frame and a III-V semiconductor bidirectional switch bare die. The lead frame includes leads and an exposed pad that is attached to the heat sink with a layer of thermal interface material (TIM) inserted between the heat sink and the exposed pad. A substrate region of the III-V semiconductor bidirectional switch bare die is attached to the exposed pad with a layer of insulation material inserted between the substrate region and the exposed pad. The III-V semiconductor bidirectional switch bare die includes two III-V transistors that share part of the active device area and formed as a lateral device upon a single semiconductor body.

Embodiments of the present invention are directed to a package of bidirectional switch. The package includes a heat sink, a lead frame and a III-V semiconductor bidirectional switch bare die. The lead frame includes leads and an exposed pad that is attached to the heat sink with a layer of thermal interface material (TIM) inserted between the heat sink and the exposed pad. A substrate region of the III-V semiconductor bidirectional switch bare die is attached to the exposed pad. The III-V semiconductor bidirectional switch bare die includes two III-V transistors that share part of the active device area and formed as a lateral device upon a single semiconductor body. A first gate electrode and a second gate electrode of the two III-V transistors are configured to receive two respective signals to control the III-V semiconductor bidirectional switch bare die to block and conduct currents from two directions. One of a first source electrode and a second electrode of the two III-V transistors is electrically coupled to the exposed pad.

### BRIEF DESCRIPTION OF DRAWINGS

For a better understanding of the invention, embodiments of the invention will be described in accordance with the following drawings, which are used for illustrative purpose only. The drawings illustrate only some of the features in an embodiment. It should be understood that the drawings are not necessarily to scale. Like elements are provided with like reference numerals in different appended drawings.

FIG. 1 is a cross-sectional side view of a package 100 of bidirectional switch for top side cooling.

FIG. 2A is a cross-sectional side view of a package 200 of bidirectional switch for top side cooling in accordance with an example embodiment of the present disclosure.

FIG. 2B is a cross-sectional layered view of the III-V semiconductor bidirectional switch bare die 10 and an example arrangement of it in accordance with an example embodiment of the present disclosure.

FIG. 3A is a cross-sectional side view of a package 300 of bidirectional switch for top side cooling in accordance with an example embodiment of the present disclosure.

FIG. 3B is a cross-sectional layered view of the III-V semiconductor bidirectional switch bare die 10 and an example arrangement of it in accordance with an example embodiment of the present disclosure.

FIG. 4 is a cross-sectional side view of a package 400 of bidirectional switch for top side cooling in accordance with an example embodiment of the present disclosure.

FIG. 5 is a cross sectional layered view of the III-V semiconductor bidirectional switch bare die 10 and an example arrangement of it in accordance with an example embodiment of the present disclosure.

### DETAILED DESCRIPTION OF THE INVENTION

Detailed description of the embodiments is provided merely to give examples and not intended to be limiting. Plenty of details are provided to assist the reader in gaining a comprehensive understanding of the present invention. However, many other ways of implementing the disclosure of this application described herein will be apparent. Description of materials and methods that are known in the art may not be addressed in this disclosure for simplicity.

Throughout the specification and claims, the articles “a,” “an,” and “the” are intended to include the plural forms as well, unless the context clearly indicates otherwise. These phases “one embodiment”, “an embodiment”, “an example” and “examples” are not necessarily directed to the same embodiment or example. Furthermore, the features, structures, or characteristics may be combined in one or more embodiments or examples. Throughout the specification and claims, the ordinal numbers “first,” “second,” and “third” are intended to indicate different features and are not intended to indicate the order. For example, “a second gate electrode” is an electrode different from the “a first gate electrode”.

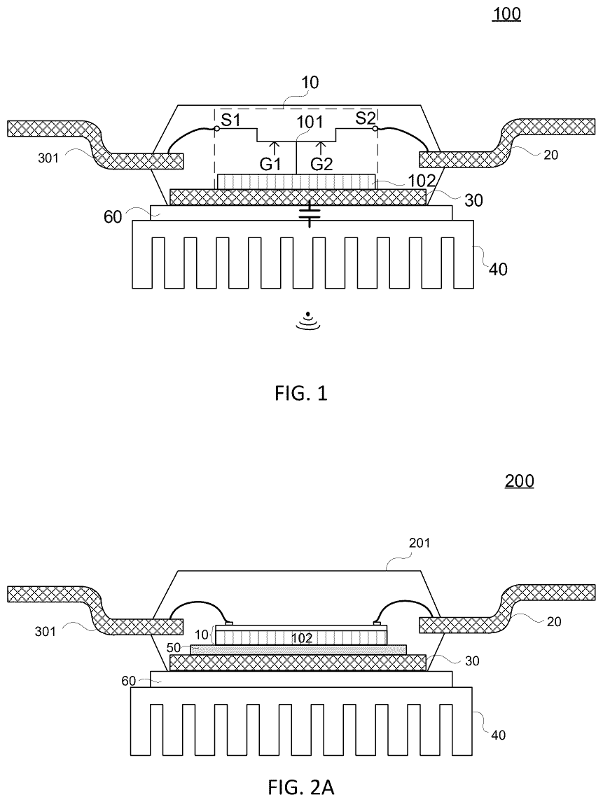

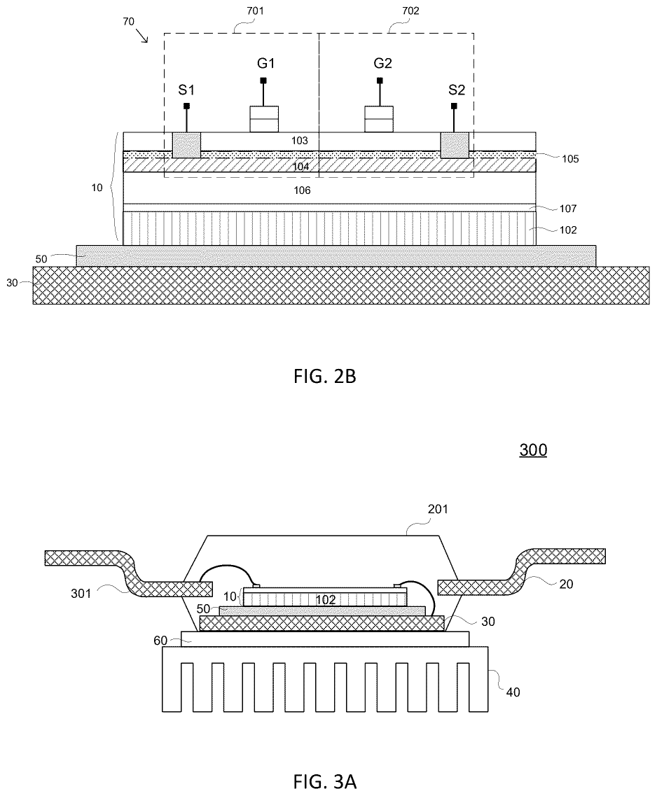

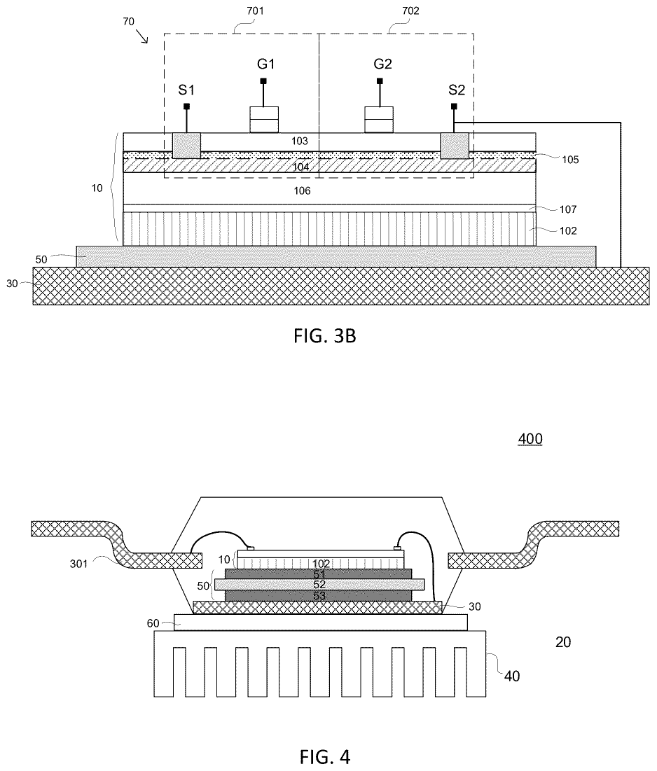

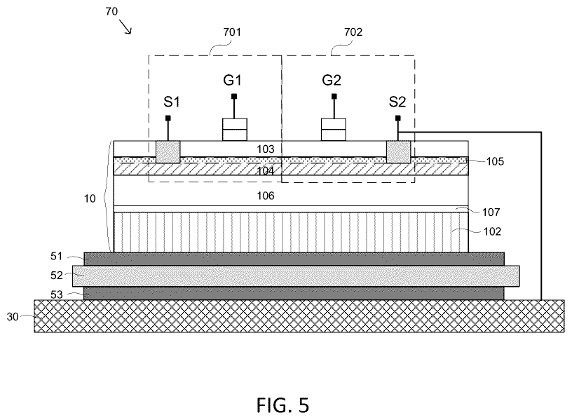

Exemplary packages are illustrated in figures according to some embodiments of this disclosure. FIG. 1 is a schematic view of a package 100 of the III-V semiconductor bidirectional switch bare die 10. FIG. 2A and FIG. 2B are schematic views of a package 200 in accordance with an example embodiment of the present disclosure. FIG. 3A and FIG. 3B are schematic views of a package 300 in accordance with an example embodiment of the present disclosure. FIG. 4 and FIG. 5 are schematic views of a package 400 in accordance with an example embodiment of the present disclosure. The following description collectively references each of FIGS. 1-5.

In the example of FIG. 1, a shared common drain 101 of the III-V semiconductor bidirectional switch bare die 10 is electrically connected to the exposed pad 30 through an electrical connection to the substrate region 102. A first source electrode S1 and a second source electrode S2 of the III-V semiconductor bidirectional switch bare die 10 may be configured to couple to the leads 301 through wire bonding or other known techniques of electrical connections. A first gate electrode G1 and a second gate electrode G2 of the III-V semiconductor bidirectional switch bare die 10 may be configured to receive two respective signals to control the III-V semiconductor bidirectional switch bare die 10 to block and conduct currents from two directions.

Referring to FIG. 1, to ensure efficient heat transfer between the exposed pad 30 and the heat sink 40, the layer of TIM 60 is inserted. While the layer of TIM 60 is designed to facilitate heat transfer, it is typically also an electrically insulative material. Therefore, as schematically illustrated in FIG. 1, there is a parasitic capacitor between the exposed pad 30 and the heat sink 40. One problem associated with the package 100 of the III-V semiconductor bidirectional switch bare die 10 relates to a high noise emission, originating from this capacitive coupling between the exposed pad 30 of the lead frame 20 and the heatsink 40. During operations of the III-V semiconductor bidirectional switch bare die 10, when the first gate electrode G1 receives an “ON” signal and the second gate G2 electrode receives an “OFF” signal, the exposed pad 30 is switched to a potential at the first source electrode S1; when the first gate electrode G1 receives an “OFF” signal and the second gate electrode G2 receives an “ON” signal, the exposed pad 30 is switched to a potential at the second source electrode S2; as a result, the exposed pad 30 potential fluctuates and drives a current into the heat sink 40 through the capacitive coupling, making the heatsink 40 become a negatively effective antenna for noise radiation due to its large size.

FIG. 2A schematically illustrates a cross-sectional side view of a package 200 of bidirectional switch for top side cooling in accordance with one embodiment of the present disclosure. The package 200 includes the lead frame 20 that may include the exposed pad 30 and a plurality of leads 301. The III-V semiconductor bidirectional switch bare die 10 where two III-V transistors share part of the active device area and formed as a lateral device upon a single semiconductor body may be arranged on the exposed pad 30. In an exemplary embodiment of the present disclosure, the substrate region 102 of the III-V semiconductor bidirectional switch bare die 10 is not directly attached to the exposed pad 30. As shown in the FIG. 2A, a layer of insulation material 50 is sandwiched between the substrate region 102 and the exposed pad 30 to isolate them from each other. Because of the existence of the layer of insulation material 50, the variation of a potential of the substrate region 102 during operation won't affect the exposed pad 30 potential, making the heatsink 40 become quiet. The package 200 may further include an encapsulation body 201 that may at least partly cover the III-V semiconductor bidirectional switch bare die 10, the exposed pad 30 and the leads 301. The exposed pad 30 exposes at least part of one of its surface from the encapsulation body 201, the exposed surface of the exposed pad 30 is configured to be mounted to the heatsink 40 with the layer of TIM 60 for achieving top side cooling.

FIG. 2B schematically illustrates a cross sectional layered view of the III-V semiconductor bidirectional switch bare die 10 and an example arrangement of it. The III-V semiconductor bidirectional switch bare die 10 can be made of a wide range of group IV semiconductor material such as Si, compound group IV semiconductor material such as SiC, and group III-V semiconductor materials such as GaN, AlGaN, etc. In FIG. 2B, the III-V semiconductor bidirectional switch bare die 10 includes an active region having a first III-V semiconductor layer 103 and a second III-V semiconductor layer 104. The second III-V semiconductor layer 104 is formed from a material having a different band gap to the first III-V semiconductor layer 103. For example, in an embodiment of this disclosure, the first III-V semiconductor layer 103 could be GaN and the second III-V semiconductor layer 104 could be AlGaN. A layer of two-dimensional charge carrier gas channel (“2DEG”) 105 forms near the interface of first III-V semiconductor layer 103 and the second III-V semiconductor layer 104 due to polarization effects and serves as a two-dimensional current conducting channel. The first III-V semiconductor layer 103, the second III-V semiconductor layer 104, the layer of 2DEG 105, the first gate electrode G1, the second electrode G2, the first source electrode S1 and the second source electrode S2 together form a first HEMT 701 and a second HEMT 702 of a bidirectional switch device 70 that the two HEMTs share one same drift region.

The III-V semiconductor bidirectional switch bare die 10 further includes a lattice transition layer 106, a nucleation layer 107 and the substrate region 102 which don't contribute directly to the conducting channel of the bidirectional switch device 70. In an embodiment of this disclosure, the substrate region 102 may be formed from group IV semiconductor material such as Si or group III-V semiconductor material such as type III semiconductor nitride.

Referring to FIG. 3A and FIG. 3B, they schematically show views of a package 300 in accordance with an example embodiment of the present disclosure. Compared to the schematical views of the package 200 in FIG. 2A and FIG. 2B, the main difference comes from how to configure the potential of the exposed pad 30. In the embodiment of FIG. 3A and FIG. 3B, the second source electrode S2 is configured to electrically couple to the exposed pad 30 by wire bonding. Those skilled in the art should understand that the exposed pad 30 may be electrically coupled to the first source electrode S1 instead of the second source electrode and other techniques for electrical connection could be used to tie the potential at the exposed pad 30 to the potential at the second source electrode S2 or the potential at the first source electrode S1.

The III-V semiconductor bidirectional switch bare die 10 of operates as follows, when the first gate electrode G1 receives an “ON” signal and the second gate G2 receives an “OFF” signal, the substrate region 102 switched to the potential at the first source electrode S1; when the first gate electrode G1 receives an “OFF” signal and the second gate electrode G2 receives an “ON” signal, the substrate region 102 is switched to the potential at the second source electrode S2. In the absence of any further measures, the potential of the substrate region 102 vary during operation. In the embodiment of FIG. 3A and FIG. 3B, the exposed pad 30 is tied to, for example, the second source electrode S2. In many application circuits of bidirectional switch, the potential at the second source electrode S2 and/or the potential at the first source electrode S1 follows a voltage that varies in a sinusoidal mannan, instead of a fixed voltage value. Therefore, by tying the exposed pad 30 to the first source electrode S1 or the second source electrode S2, the potential of the exposed pad 30 changes smoothly as a sinusoidal wave, rather than fluctuates between the potential at first source electrode S1 and the potential at the second source electrode S2. The noise radiation problem of the heatsink 40 could be greatly alleviated and hence the reliability of the package of the III-V semiconductor bidirectional switch bare die 10 is greatly improved. While in the schematical views of FIG. 3A and FIG. 3B, the layer of insulation material 50 is shown between the exposed pad 30 and the substrate region 102 of the III-V semiconductor bidirectional switch bare die 10, but in other embodiments of the present disclosure, the layer of insulation material 50 could be omitted.

To isolate the substrate region 102 and the exposed pad 30 from each other, the layer of insulation material 50 is made from a thin layer of ceramic such as Al₂O₃, Si₃N₄, AlN, SiO₂ and etc., or a thin layer of polymers such as epoxy, polyimide and etc. Referring to FIG. 4 and FIG. 5, in an embodiment of this disclosure, the layer of insulation material 50 is a direct bonded copper (“DBC”) substrate having a ceramic base layer 52 coated by a first copper foil 51 and a second copper foil 53 on its two opposed surfaces. The first copper foil 51 and the second copper foil 53 is directly bonded to the ceramic base layer 51 by a high temperature process that ensures a strong mechanical and thermal connection between the copper and the ceramic, making the DBC substrate ideal for high-power and high-heat conditions. Al₂O₃ and AlN are commonly used material for the ceramic base layer 51 that provide high thermal conductivity and excellent insulation properties.

While some embodiments of the present invention have been described in detail above, it should be understood, of course, these embodiments are for exemplary illustration only and are not intended to limit the scope of the present invention. Various modifications are contemplated, and they obviously will be resorted to by those skilled in the art without departing from the spirit and the scope of the invention.

1. A package of bidirectional switch, comprising:
a heat sink;
a lead frame comprising leads and an exposed pad which is attached to the heat sink with a layer of thermal interface material (TIM) inserted between the heat sink and the exposed pad;
a III-V semiconductor bidirectional switch bare die comprising a substrate region which is attached to the exposed pad with a layer of insulation material inserted between the substrate region and the exposed pad;
wherein the III-V semiconductor bidirectional switch bare die comprises: two III-V transistors that share part of the active device area and formed as a lateral device upon a single semiconductor body.

2. The package of claim 1, wherein a first gate electrode and a second gate electrode of the two III-V transistors are configured to receive two respective signals to control the III-V semiconductor bidirectional switch bare die to block and conduct currents from two directions; and one of a first source electrode and a second electrode of the two III-V transistors is electrically coupled to the exposed pad.

3. The package of claim 1, wherein the two III-V transistors are two GaN high-electron-mobility transistors which are integrally formed in the III-V semiconductor bidirectional switch bare die.

4. The package of claim 1, wherein the package further comprises an encapsulation body that at least partly cover the III-V semiconductor bidirectional switch bare die, the exposed pad and the leads; wherein the exposed pad exposes at least part of one of its surface from the encapsulation body.

5. The package of claim 1, wherein the layer of insulation material comprises a ceramic base layer coated with a first copper foil and a second copper foil.

6. A package of bidirectional switch, comprising:
a heat sink;
a lead frame comprising leads and an exposed pad which is attached to the heat sink with a layer of thermal interface material (TIM) inserted between the heat sink and the exposed pad;
a III-V semiconductor bidirectional switch bare die comprising a substrate region which is attached to the exposed pad;
wherein the III-V semiconductor bidirectional switch bare die comprises: two III-V transistors that share part of the active device area and formed as a lateral device upon a single semiconductor body;
wherein a first gate electrode and a second gate electrode of the two III-V transistors are configured to receive two respective signals to control the III-V semiconductor bidirectional switch bare die to block and conduct currents from two directions; and one of a first source electrode and a second electrode of the two III-V transistors is electrically coupled to the exposed pad.

7. The package of claim 6, wherein the two III-V transistors are two GaN high-electron-mobility transistors which are integrally formed in the III-V semiconductor bidirectional switch bare die.

8. The package of claim 6, wherein the package further comprises an encapsulation body that at least partly cover the III-V semiconductor bidirectional switch bare die, the exposed pad and the leads; wherein the exposed pad exposes at least part of one of its surface from the encapsulation body.

9. The package of claim 6, wherein the layer of insulation material comprises a ceramic base layer coated with a first copper foil and a second copper foil.
